(19) United States
(12) Patent Application Publication
(10) Pub. No.: US 2004/0073656 A1
(43) Pub. Date: Apr. 15, 2004

(54) Testing multi-protocol message and connection applications with reusable test components sharing dynamically generated data and limited hardware resources

(76) Inventors: Stephen C. Booth, Fort Collins, CO (US); Abhay A. Sathe, Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/268,670

(22) Filed: Oct. 11, 2002

(51) Int. Cl. G06F 15/173; G01R 31/28

(52) U.S. Cl. 709/224; 714/712

(57) ABSTRACT

A test system tests multi-protocol message and connection oriented applications with reusable test components that share dynamically generated data and limited hardware resources. The test system includes a test agent, which includes a test scheduler scheduling tests, and an enhanced sequence test including a sequence of test components dynamically generating and sharing the data among the test components. The test components are re-usable. A data store such as a memory stores the dynamically generated data for use by a later component test, in a user-defined name-value combination.

### BACKGROUND OF THE INVENTION

1. Field of the Invention

The present invention relates to computer-based diagnostic management systems, and, more particularly, to computer-based diagnostic management systems in which software test agents execute testing transactions in a mixed protocol testing environment.

2. Description of the Related Art

Testing environments, more particularly, computer-based testing environments, exist which support the execution of a sequence of operations referred to as test transactions. The operations within a test transaction generally use a particular protocol or a highly-related and specific subset of protocols.

The test transactions of the related art are static. That is, the test transactions of the related art do not generally allow data dynamically generated by an operation to change the real-time behavior of any number of arbitrary subsequent operations.

Moreover, multi-protocol applications are becoming popular with wireless Mobile (Cell) phone users. Some examples of these multi-protocol applications are e-mail to short messages and vice versa, web (HTTP) to short messages, and others. These applications have two common characteristics:

(1) These applications use a combination of Internet and telephony protocols to complete the application transaction. Such protocols include SMS (short message service), WAP (wireless application protocol), HTTP (hypertext transfer protocol), and SMTP (simple mail transfer protocol); and

(2) some parts of the application's transaction are connection-based (that is, connect to a web site and support data upload/download) while other parts are connectionless (that is, use a message delivery system such as SMS).

Traditional tests for these types of applications are monolithic (that is, one predefined, static block) tests that combine one or more of these protocols to complete the testing of these applications. That is, the traditional test is a single unit, which achieves a single purpose such as testing SMS to SMS delivery or mail to SMS delivery.

However, the traditional tests are inflexible and unable to accommodate extensions to the application transaction, thus requiring test modification. This test modification includes re-defining, re-recording, and re-executing the entire test.

In addition, the traditional tests lack an elegant mechanism to define, store, and share data dynamically generated in each test run. That is, the use of data dynamically generated during one test run by another test run requires manual intervention, or uses nonstandard data formats.

Further, the traditional tests do not make efficient use of limited hardware resources (such as modems). During traditional testing, one or more resources are dedicated to a test for the duration of the test, regardless of whether the resource is actively used for the duration of the test. Thus, other tests are precluded from using one or more resources for the duration of the test.

FIG. 1 is a diagram showing an example of a testing infrastructure 100 of the related art, such as provided by FIREHUNTER Mobile Service Assurance Product by Agilent Technologies. As shown in FIG. 1, a test sequence 110 of the related art includes a series of test components, 1-4, executed sequentially based upon a start sequence, a control sequence of operations, and an end of sequence. The test components are not aware of each other.

Generally, as is known in the art, operations within a sequence test are referred to as children of the sequence test, and the sequence test is the parent of all operations included in the sequence test. However, in the related art, there is no data sharing among children of the sequence test.

### SUMMARY OF THE INVENTION

Accordingly, the present invention defines a mechanism that allows an operation to capture and store dynamic data for use by any subsequent operation defined within the same test transaction or hierarchy of test transactions, and to use data dynamically generated by any previous operation within the same test transaction or hierarchy of test transactions.

In addition, the present invention combines component tests into a sequence to create meaningful operations to run an application transaction. Examples of component tests include tests that establish a connection, tests that can connect to web sites and “get” or “post” data, and tests that can send or receive messages. The present invention allows easy alteration of the sequence of test component execution, which is advantageous when an unusual condition, such as an application error, occurs. Thus, the present invention shows clearly the individual operation in the application sequence that failed and allows reporting of catastrophic failures such as malfunctioning devices. Test environments of the related art, such as FIREHUNTER by Agilent Technologies, provide facilities to create these sequences of test components with easy “drag and drop” actions in a graphical user interface.

Additional aspects of the invention will be set forth in part in the description which follows, and, in part, will be obvious from the description, or may be learned by practice of the invention.

An apparatus includes a test system testing multi-protocol message and connection oriented applications with reusable test components that share dynamically generated data and limited hardware resources. The test system includes a test agent, which includes a test scheduler scheduling tests, and an enhanced sequence test including a sequence of test components dynamically generating and sharing the data among the test components. The test components are re-usable. A data store, such as computer memory, stores the dynamically generated data for use by a later component test, in a user-defined name-value combination.

The present invention provides an apparatus comprising a test system testing multi-protocol message and connection oriented applications with reusable test components that share dynamically generated data and limited hardware resources.

The present invention also includes a method of a test system testing multi-protocol message and connection oriented applications with reusable test components that share dynamically generated data and limited hardware resources.

In addition, the present invention provides a computer-readable medium which when executed by a computer, causes the computer to execute functions including testing multi-protocol message and connection oriented applications with reusable test components that share dynamically generated data and limited hardware resources.

### BRIEF DESCRIPTION OF THE DRAWINGS

Aspects of the invention will become apparent and more readily appreciated from the following description of the preferred embodiments, taken in conjunction with the accompanying drawings of which:

FIG. 1 is a diagram showing an example of a testing infrastructure of the related art, such as FIREHUNTER Mobile Service Assurance Product by Agilent Technologies.

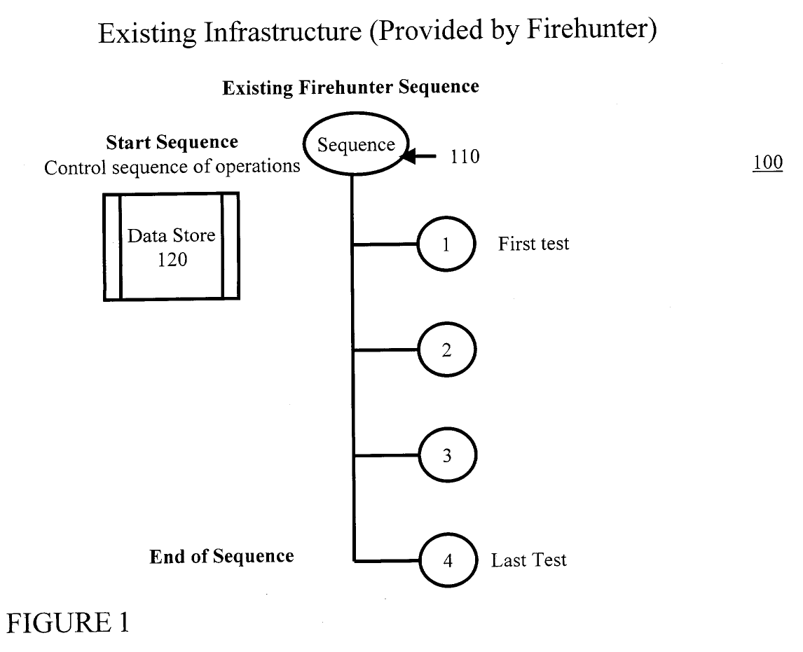

FIG. 2 is a diagram of a multi-protocol test system of the present invention.

FIG. 3 is a diagram of a first aspect of the present invention, that is a sequence of operations which mimic any mixed protocol application.

FIG. 4 is a diagram showing an example of details of component and data exchange in the enhanced sequence test of the present invention.

FIG. 5 shows the use of storage (or data store or memory) within a sequence of the present invention to save changing (or dynamic) data which will be used by a following test component or part within the sequence of the present invention.

FIG. 6 shows an example of component based testing of the present invention.

FIG. 7 is a diagram showing a multi-protocol test system of the present invention using limited resources.

### DETAILED DESCRIPTION OF THE PREFERRED EMBODIMENTS

Reference will now be made in detail to the present preferred embodiments of the present invention, examples of which are illustrated in the accompanying drawings, wherein like reference numerals refer to like elements throughout.

The present invention includes the feature of sharing dynamically generated data in a mixed-protocol testing environment. In addition, the present invention includes the feature of testing multi-protocol message and connection oriented applications with reusable test components that share dynamically generated data and limited resources.

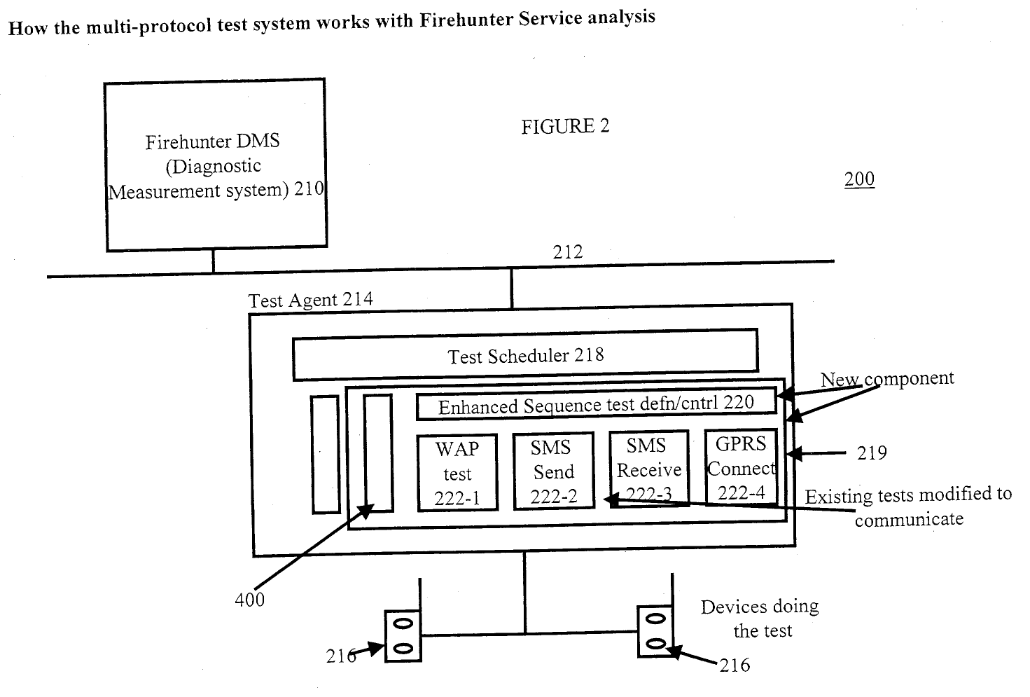

Both of the foregoing features of the present invention are explained in detail beginning with FIG. 2.

FIG. 2 is a diagram of a multi-protocol test system 200 of the present invention. As shown in FIG. 2, the multi-protocol test system 200 of the present invention includes a diagnostic management system (DMS) 210 (for example, a FIREHUNTER DMS by Agilent Technologies) interfacing through a network such as the Internet 212 to a test agent 214, which, in turn, applies tests to devices 216.

Included in the test agent 214 is test scheduler 218 which creates and maintains the schedule of tests to be executed by the test agent 214.

Test scheduler 218 is in communication with enhanced sequence test 219 of the present invention. Enhanced sequence test 219 of the present invention is also included in test agent 214.

The enhanced sequence test 219 of the present invention provides for sharing of dynamically generated data in a mixed-protocol testing environment and includes reusable test components which share the dynamically generated data.

The enhanced sequence test 219 of the present invention includes enhanced sequence test definition and control 220 and tests 222. The tests 222 include existing tests 222-1 (WAP test), 222-2 (SMS send), 222-3 (SMS receive), 222-4 (GPRS (general packet radio service) Connect), etc., which are included in, controlled by, and modified to communicate with the enhanced sequence test definition and control 220 of the present invention. These existing tests 222 are reusable test components which share data generated dynamically and are of mixed protocols. These test components 222 are then applied to devices doing the test 216. The present invention is not limited to the above listed protocols which exemplify the present invention.

One embodiment of the foregoing system 200 of the present invention would be as an extension of the FIREHUNTER service assurance product by Agilent Technologies. For example, the FIREHUNTER sequence test would be modified as the enhanced sequence test 219 of the present invention to include test transactions 222-1, 222-2, 222-3, and 222-4. Operations (children) would be the foregoing individual test transactions 222 within the enhanced sequence test 219 in which a hierarchy of test sequences is permitted. Consequently, a sequence test may itself be an operation (child) included in the enhanced sequence test 219 of the present invention.

In the enhanced sequence test 219 of the present invention, each operation allows a user-defined program to (1) parse any raw data produced by the operation, and (2) return dynamic data to the operation in the form of name=value pairs. Each operation may have additional, internal or external code that produces the dynamic data.

Also in the enhanced sequence test 219 of the present invention, instances of the sequence test implement a data store available only to the sequence test and operations (or test components) beneath the sequence test in a hierarchy. An operation may store data in its immediate parent sequence test, or in any sequence test in its hierarchy. The operation has control over which data store it uses.

In addition in the enhanced sequence test 219 of the present invention, an operation may retrieve data from the data store of any sequence test in its hierarchy. The operation can limit itself to using the data store of its immediate parent or not, as makes sense for the operation.

Further in the enhanced sequence test 219 of the present invention, the sequence test hierarchy defines the access to the data store. Access to the data store travels in one direction, toward the root sequence test in the hierarchy.

Moreover, in the enhanced sequence test 219 of the present invention, an instance of a sequence test creates a new data store each time the instance of the sequence test is executed.

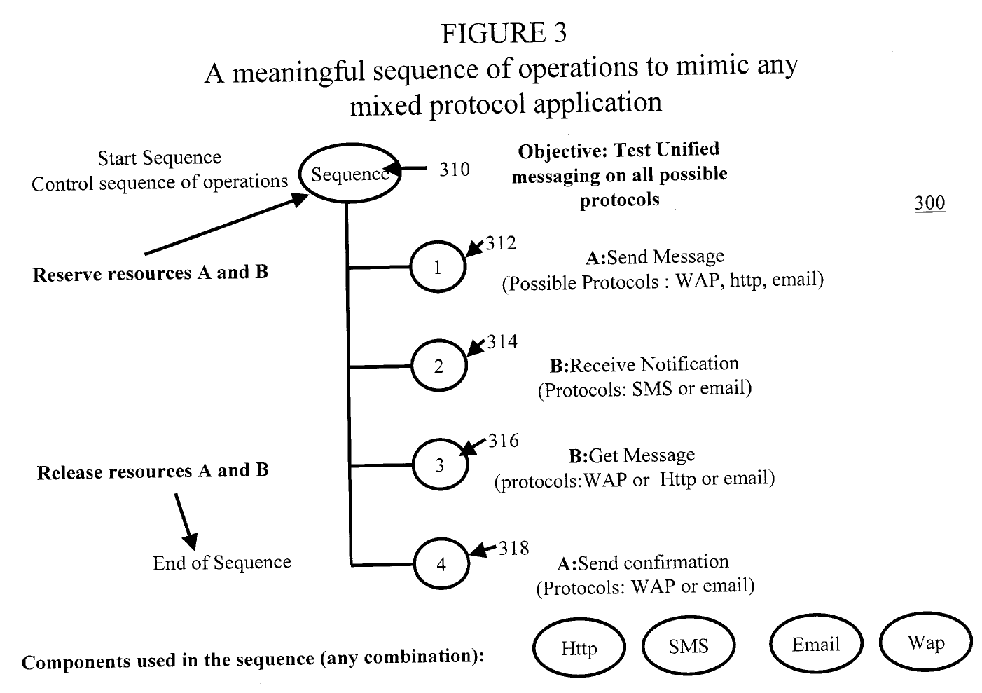

FIG. 3 is a diagram of a first aspect of the present invention, that is a sequence of operations 300 which mimic any mixed protocol application. The sequence of operations 300 is scheduled by the test scheduler 218 and executed by the enhanced sequence test 219 on the devices 216.

In the example of FIG. 3, the objective of the sequence of operations 300 is to test unified messaging on all possible protocols. The components used in the sequence of operations 300 include HTTP, SMS, Email, and WAP, in any combination. However, the present invention is not limited to the foregoing protocols. The multi-protocols supported by the present invention include any protocols for which a test can be written that can produce data that can be parsed for dynamic content.

Referring now to FIG. 3, the sequence of operations 300 of the enhanced sequence test 219 reserves resources A and B (that is, devices doing the test 216) in start sequence/control sequence of operations 310. Then, in a first component test 312, the Send Message function of resource A is tested using possible protocols of WAP, HTTP, or Email. Next, in a second component test 314, the Receive Notification function of resource B is tested using possible protocols of SMS or Email. Then, in a third component test 316, the Get Message function of resource B is tested using possible protocols WAP, HTTP, or Email. Lastly in the sequence of operations 300 included in the enhanced sequence test 219, in a fourth component test 318, the Send Confirmation function is tested using possible protocols WAP or Email. After completion of the fourth component test 318, resources A and B are released and become available for use by other tests.

In the sequence of operations 300 of the enhanced sequence test 219 of the present invention, component tests 312, 314, 316, and 318 are included, dynamically share data between each of the component tests 312, 314, 316, and 318, and test a mix of protocols WAP, HTTP, Email, and, SMS and thus provide a multi-protocol testing environment.

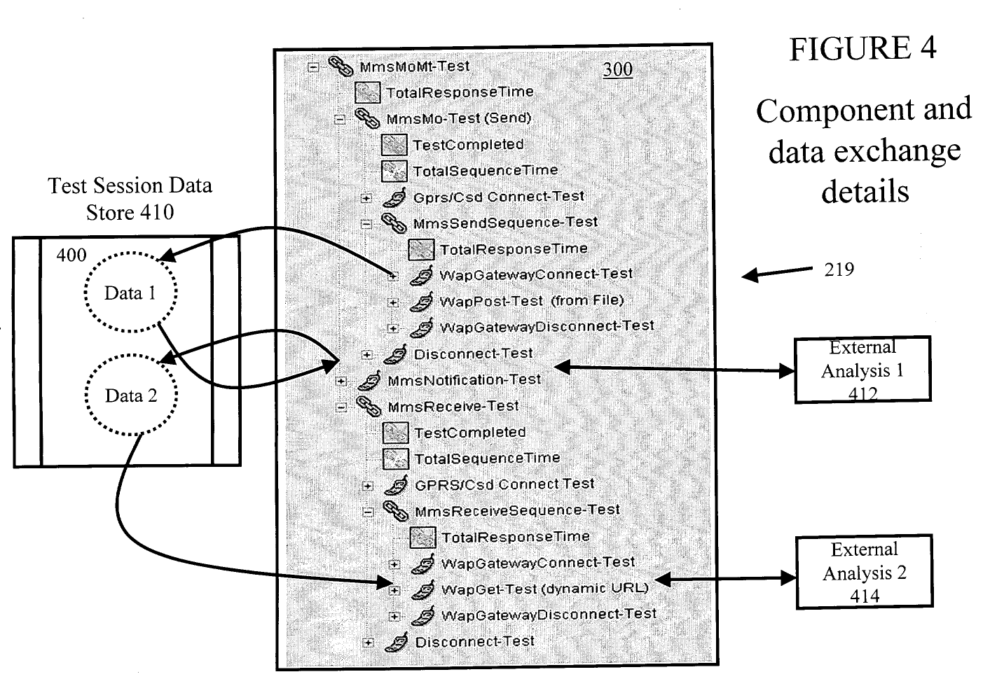

FIG. 4 is a diagram showing an example of details of component and data exchange in the enhanced sequence test 219 of the present invention. As shown in FIG. 4, a sequence of operations 300 is executed by the enhanced sequence test 219 of the present invention. The sequence of operations 300 shown in FIG. 4 includes, for example, a WAP Post Test. The WAP Post Test generates Data 1, which is stored in a data store such as memory 400 of the test agent 214 during a test session data store operation 410. Data 1 is read from the memory 400 and used in the MmsNotification Test, which conducts External Analysis 1 (412) and produces Data 2. Data 2 is also stored in the memory 400 and is used by the WAPGET Test (dynamic URL) during External Analysis 2 (414).

That is, the enhanced sequence test 219 of the present invention extracts data (Data 1) from the WAP Post Test and stores that information in memory 400 by a name defined by a user, that is a tester or a user of the test system. That extracted and stored data (Data 1) is dynamically generated data. Subsequent to storing the extracted data (that is, Data 1), a component test executed later in the sequence 300 (MMS Notification Test) retrieves that data by name (Data 1) and uses the data during the MMS Notification Test. Likewise, Data 2 is extracted, stored, and used in a similar manner. The enhanced sequence test 219 of the present invention allows the extraction and use of meaningful data during the enhanced sequence test 219.

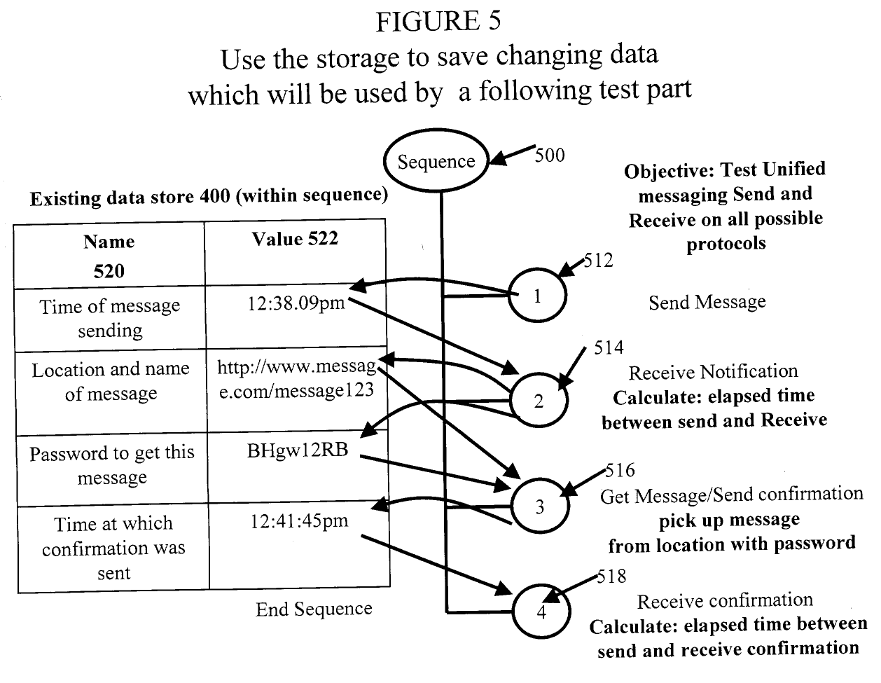

FIG. 5 shows the use of storage (or data store or memory 400) within a sequence 500 to save changing (or dynamic) data which will be used by a following test component or part within the sequence 500. Sequence 500 of FIG. 5 corresponds to sequence 300 of FIG. 3. Sequence 500 is executed by the enhanced test sequence 219 of the present invention. The data dynamically generated and used during enhanced sequence 219 of the present invention is stored as regular expressions (that is, name-value pairs) in memory 400. A user can predefine the names in which the values will be stored. Moreover, the user may provide rules to parse or execute a user-defined program to parse the data.

Referring now to FIG. 5, the objective of the example sequence 500 is to test unified messaging Send and Receive on all possible protocols. Component tests 1 (512), 2 (514), 3 (516), and 4 (518) of sequence 500 produce/use data stored in memory 400 as Name 520 and Value 522. The Value 522 is retrieved using the Name 520 by the component tests of sequence 500.

More particularly, component test 1 512 of sequence 500 executes a Send Message and produces data of value 12:38:09 pm stored in memory 400 as name Time of message sending. Component test 2 (514) Receive Notification then reads data of value 12:38:09 pm from memory 400 by name Time of message sending and uses the read data to calculate the elapsed time between the Send (512) and the Receive (514). Next, component test 2 (514) stores in memory 400 the value (522) of http://www.message.com/message 123 in name (520) Location and name of message. Component test 2 (514) also stores in memory 400 the value (522) BHgw12RB in the name (520) Password to get this message.

Subsequently, component test 3 (516) Get Message/Send information reads from memory 400 data of value http://www.message.com/message 123 from name (520) Location and name of message. Component test 3 (516) also reads from memory 400 the value (522) BHgw12RB from the name (520) Password to get this message. Component test 3 (516) then uses both of the foregoing data to pick up a message from the indicated location with the password.

Component test 3 (516) then stores value (522) 12:41:45 pm in memory 400 by name (520) Time at which confirmation was sent. Component test 4 (518) then reads from memory 400 value (522) 12:41:45 pm by name (520) Time at which confirmation was sent and uses the foregoing data to calculate an elapsed time between send and retrieve information.

FIG. 5 shows how component test n generates data to be used by component test n+1, n+2, etc., during a sequence test 219.

As shown in FIG. 5, the present invention provides safe, dynamic data sharing by:

(1) defining and operating test transaction hierarchies,

(2) providing for operations (that is, test components) to parse, directly or indirectly, raw test data to produce the dynamic data,

(3) storing the dynamic data (in one or more data stores) by the operations,

(4) retrieving by operations the dynamic data stored by previous operations within the same test transaction (or enhanced sequence test) or hierarchy of test transactions,

(5) limiting access to a data store to operations defined within a test transaction and/or hierarchy of test transactions, and

(6) cleaning out (or resetting) a data store (or memory 400) prior to executing a test transaction.

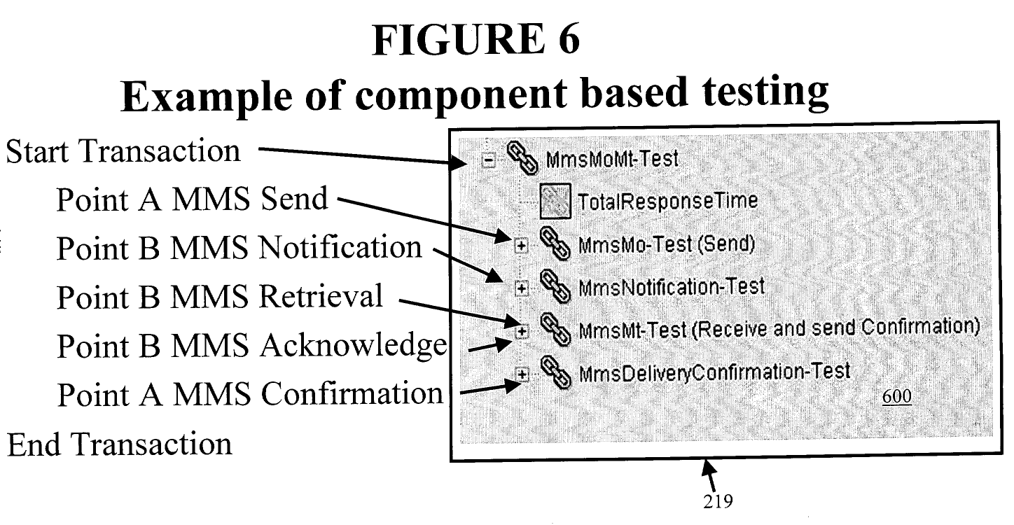

FIG. 6 shows an example of component based testing of the present invention. As shown in FIG. 6, a sequence 600 executed by enhanced sequence test 219 of the present invention includes components Point A MMS (multimedia messaging service) Send, Point B MMS Notification, Point B MMS Retrieval, Point B MMS Acknowledge, and Point A MMS Confirmation, included between the Start Transaction and the End Transaction.

As shown in FIG. 6, test components can be added, deleted, or modified within an enhanced sequence test 219 of the present invention without having to re-record the sequence test. Moreover, the component tests are re-usable and may be combined by the present invention into different patterns. In addition, the dynamically generated data by the component tests of the enhanced sequence test 219 of the present invention can change depending upon what component tests are combined into the enhanced sequence test 219.

The present invention comprises an enhanced sequence test 219 which shares dynamically generated data and provides components including test components such as Dialup, ISDN (integrated services digital network), CSD (circuit-switched data) connect test, disconnect test, SMS and WAP sequence components. In the present invention, the mechanisms of reserving resources are provided as extensions of the foregoing functionality of the enhanced sequence test 219 of the present invention. Moreover, the present invention includes a mechanism to report failures. That is, if any sequence of test components runs beyond a specified time limit, the present invention attempts to stop running tests, takes device clean-up actions such as disconnecting dialed up connections or stopping serial port communications, and returns the resource(s) to a shared pool, where a recover action may be attempted on the hardware resource(s).

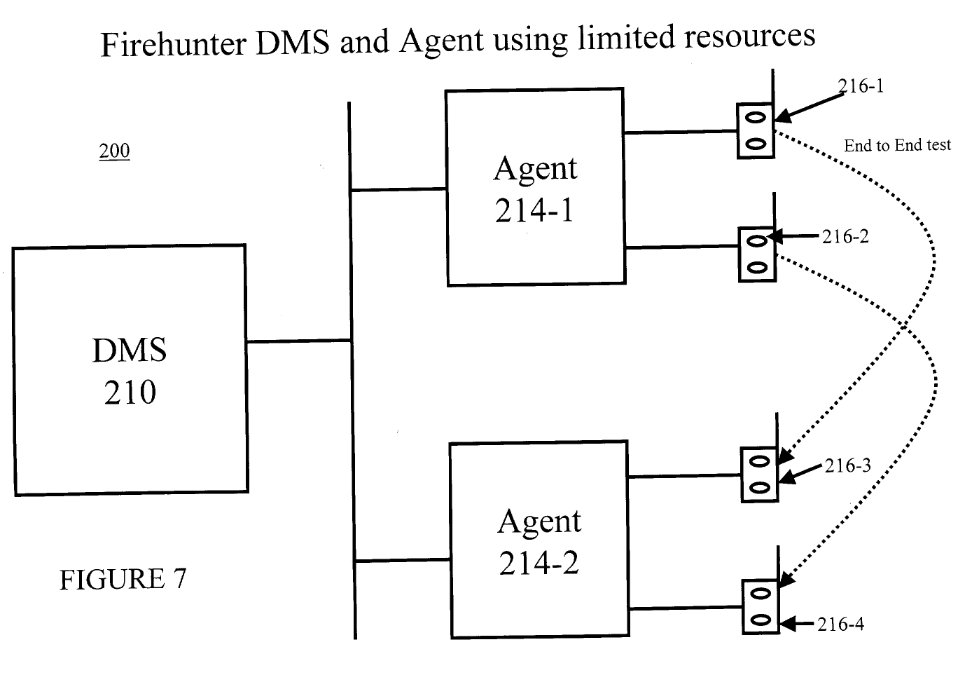

FIG. 7 is a diagram showing a multi-protocol test system 200 of the present invention using a diagnostic management system 210 and test agents 214-1, 214-2 completing end-to-end tests using limited resources 216-1, 216-2, 216-3, and 216-4. As shown in FIG. 7, each end-to-end test (enhanced sequence test 219 of the present invention) makes use of two resources 216 (for example, 216-1 and 216-3, or 216-2 and 216-4) to complete the corresponding end-to-end test. Thus, using the present invention, no single resource is dedicated to one test for the duration of that test, and each agent 214 may make use of several resources 216 during each test.

Advantageously, in the present invention, operations within a test transaction can adjust their behavior against dynamically changing conditions. A test transaction does not have to be redefined for its behavior to change. Multiple references to a test transaction can execute simultaneously on different data and with different configurations. A test transaction can use multiple protocols to achieve its goals. Operations have access only to the dynamic data pertinent to the test transaction.

Also advantageously, the present invention pictures the entire application as a transaction of discrete operations, providing a clear isolation of functions to allow much improved monitoring of progress of application transactions and isolation of faults.

In addition, the present invention allows modeling of any complex application with a smaller set of components, which allows rapid evolution of tests with the evolution of applications. More particularly, a new component needs to be added only when a new protocol is developed, which is traditionally a much slower occurrence than evolution of complex applications using existing technologies.

Moreover, the present invention provides an environment where data generated by one component can be shared with another component in the same transaction.

Further, the present invention allows much more economical sharing of hardware resources since each resource can be returned for use by other tests outside of the current transaction as soon as it use in the current transaction is complete.

Moreover, the present invention includes a computer-readable medium storing the above-mentioned enhanced sequence test of the present invention as a software program executable by a computer.

Although a few preferred embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An apparatus comprising:
a test system testing multi-protocol message and connection oriented applications with reusable test components that share dynamically generated data and limited hardware resources.

2. The apparatus of claim 1, wherein the test system comprises a test agent, said test agent comprising:
an enhanced sequence test comprising a sequence of test components dynamically generating and sharing the data among the test components.

3. The apparatus of claim 2, wherein the test components are re-usable.

4. The apparatus of claim 2, wherein the enhanced sequence test further contains a data store storing the dynamically generated data.

5. The apparatus of claim 4, wherein the data store stores the dynamically generated data in name-value combinations.

6. The apparatus of claim 5, wherein the name portions of the name-value combinations are user-defined.

7. The apparatus of claim 1, wherein the multi-protocols include protocols for which a test can be written that can produce data that can be parsed for dynamic content.

8. The apparatus of claim 2 wherein the test components test SMS, WAP, HTTP, and Email.

9. The apparatus of claim 2, wherein the test components comprise sequence tests.

10. The apparatus of claim 2, wherein the enhanced sequence test includes a hierarchy of test components, and the data is dynamically generated and shared among the test components included in the hierarchy.

11. A method of testing devices, comprising:
testing by a test system that tests multi-protocol message and connection oriented applications with reusable test components that share dynamically generated data and limited hardware resources.

12. The method of claim 2, further comprising:
executing, by an enhanced sequence test, a sequence of test components dynamically generating and sharing the data among the test components.

13. The method of claim 12, further comprising:
reusing the test components in various sequence tests included in the enhanced sequence test.

14. The method of claim 11, further comprising:
storing the dynamically generated data in a memory in a name-value combination.

15. The method of claim 14, wherein the name of the name-value combination is user-defined.

16. The method of claim 11, further comprising:
combining operations in a hierarchy in the enhanced sequence test, said operations including test components and sequence tests.

17. The method of claim 16, further comprising:
dynamically-generating and sharing the data among the operations included in the hierarchy.

18. A computer-readable medium storing a program which when executed by a computer causes the computer to execute the functions comprising:
testing by a test system that tests multi-protocol message and connection oriented applications with reusable test components that share dynamically generated data and limited hardware resources.

19. The computer-readable medium of claim 18, further comprising:
executing, by an enhanced sequence test, a sequence of test components dynamically generating and sharing the data among the test components.

20. The computer-readable medium of claim 19, further comprising:
reusing the test components in various sequence tests included in the enhanced sequence test.

21. The computer-readable medium of claim 18, further comprising:
storing the dynamically generated data in a memory in a name-value combination.

22. The computer-readable medium of claim 21, wherein the name of the name-value combination is user-defined.

23. The computer-readable medium of claim 18, further comprising:
combining operations in a hierarchy in the enhanced sequence test, said operations including test components and sequence tests.

24. The computer-readable medium of claim 23, further comprising:
dynamically generating and sharing the data among the operations included in the hierarchy.
